(19) United States
(12) Patent Application Publication
(10) Pub. No.: US 2011/0023939 A1
(43) Pub. Date: Feb. 3, 2011

(54) PORTABLE SOLAR CELL APPARATUS

(76) Inventors: Chien-An Chen, TAIPEI CITY (TW); Zao-Shi Zheng, TAIPEI CITY (TW)

Correspondence Address: NORTH AMERICA INTELLECTUAL PROPERTY CORPORATION, P.O. BOX 506, MERRIFIELD, VA, 22116, US

(21) Appl. No.: 12/845,781

(22) Filed: Jul. 29, 2010

(30) Foreign Application Priority Data
Jul. 31, 2009 (TW) 098125894

(51) Int. Cl. H01L 31/052

(52) U.S. Cl. 136/246

(57) ABSTRACT

A portable solar cell apparatus includes a base, a plurality of solar cell units, a light guide element, and a plurality of lens units. The solar cell units are disposed at the base. The light guide element has a plurality of integrally formed funnel-shaped light guide units. The light guide element is disposed at the base, and each of the funnel-shaped light guide units guides light to the respective solar cell unit. Each of the lens units is disposed at the respective funnel-shaped light guide unit.

### CROSS-REFERENCE TO RELATED APPLICATIONS

This Non-provisional application claims priority under 35 U.S.C. §119(a) on Patent Application No(s). 098125894 filed in Taiwan, Republic of China on Jul. 31, 2009, the entire contents of which are hereby incorporated by reference.

### BACKGROUND OF THE INVENTION

1. Field of the Invention

This invention relates to a solar cell apparatus and, more particularly, to a portable solar cell apparatus.

2. Description of the Related Art

Compared with traditional power generation, a solar cell converts solar energy to electrical energy directly by a photoelectric effect, thereby free from generating greenhouse gas and polluted gas such as carbon dioxide, nitrogen oxide, or oxysulfide and so on and provide safe and clean power.

To improve power generation efficiency of a solar cell, a conventional concentrating photovoltaic (CPV) apparatus is presented. In FIG. 1A and FIG. 1B, a photovoltaic apparatus 1 includes a base 11, a solar cell unit 12, and a Fresnel lens unit 14. The solar cell unit 12 is disposed at the base 11. The Fresnel lens unit 14 faces to the base 11, and the Fresnel lens unit 14 has a plurality of serrated protrudent portions 141. When light Y passes through the Fresnel lens unit 14, the serrated protrudent portions 141 concentrate the passed light to the solar cell unit 12. Since the solar cell unit 12 absorbs the light with enhanced intensity, the photoelectric conversion efficiency and the power generation efficiency are improved.

However, although the conventional photovoltaic apparatus has the concentrating Fresnel lens to concentrate the light, part of the light may still leak out and fail to be concentrated to the solar cell unit. To guide the leaked light to the solar cell unit, each light guide element needs to be disposed at each solar cell for guiding the leaked light to improve the light utilization. The solar cell and the light guide element need to be assembled one by one, which increases manufacturing difficulty and assembling time.

### BRIEF SUMMARY OF THE INVENTION

One objective of this invention is to provide a portable solar cell apparatus with light concentration and guide functions to improve photoelectric conversion efficiency and power generation efficiency and capable of reducing manufacturing difficulty and assembling time.

In the invention, the portable solar cell apparatus includes a base, a plurality of solar cell units, a light guide element, and a plurality of lens units. The solar cell units are disposed at the base. The light guide element has a plurality of integrally formed funnel-shaped light guide units. The light guide element is disposed at the base, and each of the funnel-shaped light guide units guides light to the respective solar cell unit. Each of the lens units is disposed at the respective funnel-shaped light guide unit.

In one embodiment of the invention, the funnel-shaped light guide units may be disposed in an array.

In one embodiment of the invention, each of the funnel-shaped light guide units may have at least one reflecting surface, and the reflecting surface may reflect part of the light passing through the corresponding lens unit to the corresponding solar cell unit.

In one embodiment of the invention, the reflecting surface may be a flat surface.

In one embodiment of the invention, the reflecting surface may be a curved surface.

In one embodiment of the invention, the solar cell units may be disposed at the base in an array.

In one embodiment of the invention, the solar cell units may be made of monocrystalline silicon, polycrystalline silicon, amorphous silicon, or a III-V material.

In one embodiment of the invention, each of the lens units may cooperate with the respective funnel-shaped light guide unit to guide and concentrate light to the respective solar cell unit.

In one embodiment of the invention, the lens units may be integrally formed.

In one embodiment of the invention, each of the lens units may be a Fresnel lens and have a plurality of light concentrating structures.

In one embodiment of the invention, the Fresnel lens may be a point concentrator, and the light concentrating structures may be arranged in homocentric circles.

In one embodiment of the invention, the light concentrating structures and the corresponding solar cell unit may be rectangles with the same length-width ratio.

In one embodiment of the invention, the Fresnel lens may be a line concentrator, and the light concentrating structures may be linear and be arranged in parallel.

In one embodiment of the invention, the solar cell units may be strip-shaped.

In one embodiment of the invention, light spots generated by concentrating light by each of the lens units may be stacked, respectively, and the shape of the light spots may correspond to that of the respective solar cell unit.

In one embodiment of the invention, each of the lens units may be made of polymethyl methacrylate, polystyrene, or polycarbonate plastic.

To sum up, according to the portable solar cell apparatus in the invention, each of the lens units and each of the solar cell units correspond to the respective funnel-shaped light guide unit, and the shape and the arrangement of the light concentrating structures of each of the lens units correspond to that of the respective solar cell unit. The light spots generated by concentrating light by each of the lens units are stacked, respectively, and the shape of the light spots corresponds to that of the respective solar cell unit. Thus, light may be completely concentrated on the solar cell units by the lens units and the reflecting surfaces of the funnel-shaped light guide units. Since the solar cell units absorb the light with enhanced intensity, the photoelectric conversion efficiency and the power generation efficiency are improved. Further, a plurality of funnel-shaped light guide units are integrally formed. The manufacturing difficulty and the assembling time of the solar cell apparatus may be reduced.

### BRIEF DESCRIPTION OF THE DRAWINGS

FIG. 1A and FIG. 1B are an assembled schematic diagram and a side view showing a conventional concentrating photovoltaic apparatus, respectively;

FIG. 2, FIG. 3, and FIG. 4 are a side view, an exploded schematic diagram, and an assembled schematic diagram showing a portable solar cell apparatus according to a first embodiment of the invention, respectively;

FIG. 5 and FIG. 6 are a side view and an exploded schematic diagram showing a portable solar cell apparatus according to a second embodiment of the invention, respectively;

FIG. 7 and FIG. 8 are a side view and an exploded schematic diagram showing a portable solar cell apparatus according to a third embodiment of the invention, respectively; and

FIG. 9 and FIG. 10 are a side view and an exploded schematic diagram showing a portable solar cell apparatus according to a fourth embodiment of the invention, respectively.

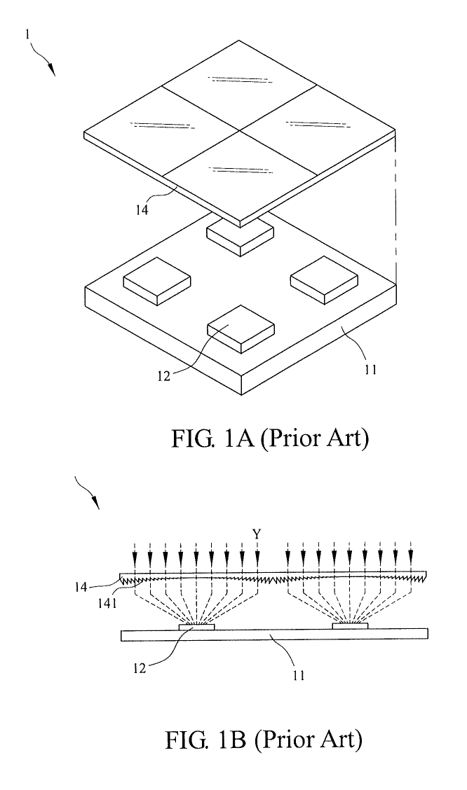

### DETAILED DESCRIPTION OF THE INVENTION

A portable solar cell apparatus according to a preferred embodiment of the invention is described.

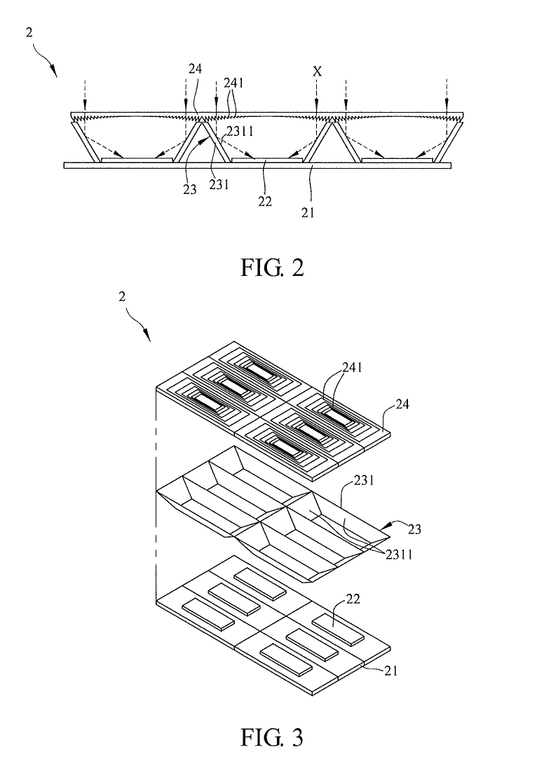

FIG. 2, FIG. 3, and FIG. 4 are a side view, an exploded schematic diagram, and an assembled schematic diagram showing a portable solar cell apparatus 2 according to the first embodiment of the invention, respectively.

In FIG. 2, FIG. 3, and FIG. 4, according to the first embodiment of the invention, the portable solar cell apparatus 2 includes a base 21, a plurality of solar cell units 22, a light guide element 23, and a plurality of lens units 24. In the embodiment, the base 21 may be made of plastic or glass. However, the invention is not limited thereto.

The solar cell units 22 are disposed at the base 21 and correspond to a funnel-shaped light guide unit 231 of the light guide element 23, respectively. In the embodiment, the solar cell units 22 are disposed at the base 21 in an array, and the solar cell units 22 may be rectangular or strip-shaped. In the embodiment, the solar cell units 22 are rectangular. The solar cell units 22 may be made of monocrystalline silicon, polycrystalline silicon, amorphous silicon, or a III-V material. However, the invention is not limited thereto.

The light guide element 23 has a plurality of integrally formed funnel-shaped light guide units 231. The light guide element 23 is disposed at the base 21, and each of the funnel-shaped light guide units 231 guides light X to the respective solar cell unit 22. In the embodiment, the number and arrangement of the funnel-shaped light guide units 231 correspond to that of the solar cell units 22 and the lens units 24.

Each of the funnel-shaped light guide units 231 has at least one reflecting surface 2311, and the reflecting surface 2311 may be a flat surface or a curved surface. The reflecting surface 2311 reflects part of light X passing through the lens unit 24 corresponding to the funnel-shaped light guide unit 231 to the solar cell unit 22.

In the embodiment, the funnel-shaped light guide units 231 are disposed at the base 21 in a 3-by-2 two-dimensional array. The number and the arrangement of the funnel-shaped light guide units 231 may depend on that of the solar cell units 22 and the lens units 24.

In the embodiment, each of the funnel-shaped light guide units 231 includes four reflecting surfaces 2311, and each of the reflecting surfaces 2311 is an inclined surface with high reflectivity. The reflecting surfaces 2311 can reflect part of light X passing through the lens unit 24 corresponding to the funnel-shaped light guide unit 231 to the solar cell unit 22. Thus, the photoelectric conversion efficiency and the power generation efficiency of the solar cell apparatus 2 can be improved.

Each of the lens units 24 is disposed at the respective funnel-shaped light guide unit 231. In the embodiment, the lens units 24 are integrally formed, and each of the lens units 24 cooperates with the funnel-shaped light guide units 231 to guide and concentrate light to the solar cell units 22. In the embodiment, the lens units 24 may be made of polymethyl methacrylate, polystyrene, or polycarbonate plastic. However, the invention is not limited thereto.

Each of the lens units 24 is a Fresnel lens and has a plurality of light concentrating structures 241. The light concentrating structures 241 may be rectangular and be arranged in homocentric circles, or they may be linear and be arranged in parallel. The shape and the arrangement of the light concentrating structures 241 correspond to that of the solar cell units 22, respectively. Further, light spots generated by concentrating light by each of the lens units 24 are stacked, respectively, and the shape of the light spots corresponds to that of the respective solar cell unit 22.

In the embodiment, the Fresnel lens is a point concentrator. The light concentrating structures 241 are arranged in homocentric circles, and the light concentrating structures 241 and the corresponding solar cell unit 22 are rectangles with the same length-width ratio. Light X passes through the light concentrating structures 241 arranged in the homocentric circles of the Fresnel lens unit 24. Then, in the cooperation with the reflecting surfaces 2311 with the high reflectivity, light X can be completely concentrated on the rectangular solar cell unit 22 with the same length-width ratio, such that the solar cell unit 22 absorbs the light with enhanced intensity. Thus, the photoelectric conversion efficiency and the power generation efficiency of the solar cell apparatus 2 can be improved. In addition, the light guide element 23 is integrally formed. Therefore, the manufacturing difficulty and the assembling time of the solar cell apparatus 2 can be reduced.

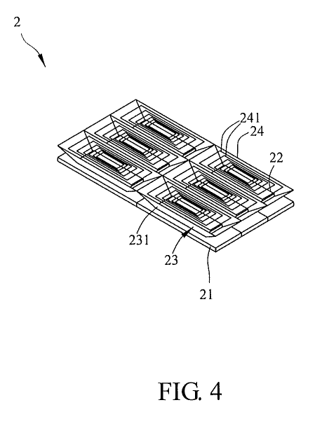

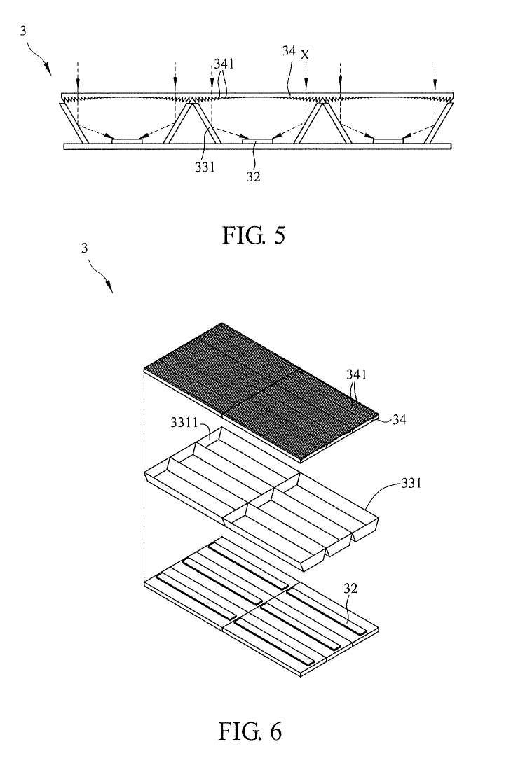

FIG. 5 and FIG. 6 are a side view and an exploded schematic diagram showing a portable solar cell apparatus 3 according to the second embodiment of the invention, respectively.

The main difference between the second embodiment and the first embodiment is that lens units 34 in the second embodiment are line concentrators. Light concentrating structures 341 are linear and are arranged in parallel, and they correspond to strip-shaped solar cell unit 32. More particularly, each of funnel-shaped light guide units 331 cooperates with the linear light concentrating structures 341. Therefore, as shown in FIG. 6, the reflecting surfaces 3311 in the direction of width are not inclined surfaces.

By the linear light concentrating structures 341 of the lens units 34 arranged in parallel and the integrally formed funnel-shaped light guide units 331, light X is completely concentrated on the strip-shaped solar cell units 32. Thus, the photoelectric conversion efficiency and the power generation efficiency of the solar cell apparatus 3 can be improved, and the manufacturing difficulty and the assembling time can be reduced.

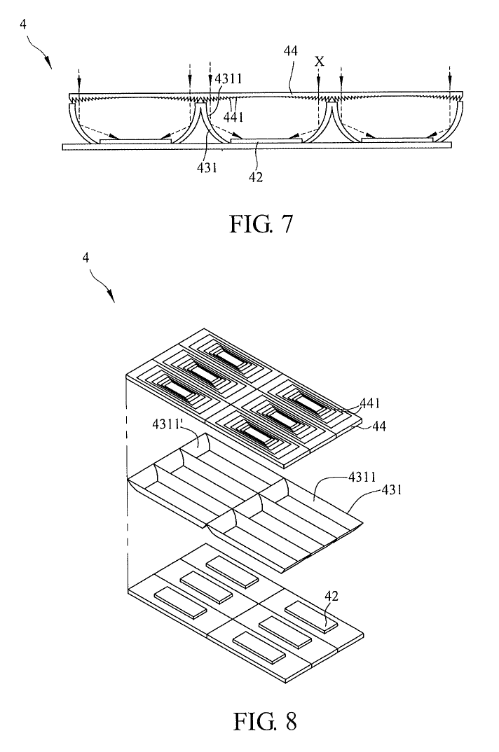

FIG. 7 and FIG. 8 are a side view and an exploded schematic diagram showing a portable solar cell apparatus 4 according to the third embodiment of the invention, respectively.

The main difference between the third embodiment and the first embodiment is that in the third embodiment reflecting surfaces 4311 in the direction of length of funnel-shaped light guide units 431 are curved surfaces. Thus, light X passing through lens units 44 corresponding to the funnel-shaped light guide units 431 can be reflected to solar cell units 42. More particularly, each of the funnel-shaped light guide units 431 cooperates with a plurality of light concentrating structures 441. Therefore, as shown in FIG. 8, reflecting surfaces 4311′ in the direction of width are inclined surfaces. Certainly, the reflecting surfaces 4311′ in the direction of width may also be curved surfaces. However, the invention is not limited thereto.

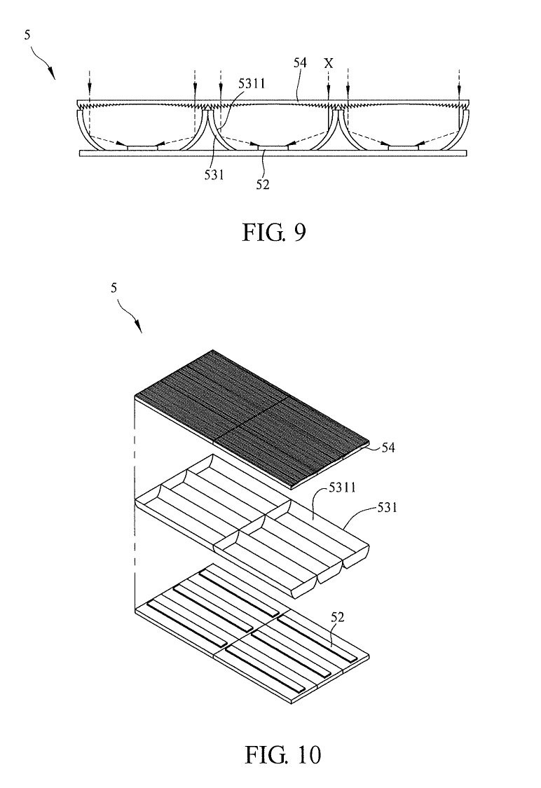

FIG. 9 and FIG. 10 are a side view and an exploded schematic diagram showing a portable solar cell apparatus 5 according to the fourth embodiment of the invention, respectively.

The main difference between the fourth embodiment and the second embodiment is that reflecting surfaces 5311 of funnel-shaped light guide units 531 in the fourth embodiment are curved surfaces. Thus, light X passing through lens units 54 corresponding to the funnel-shaped light guide units 531 can be reflected to solar cell units 52.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A portable solar cell apparatus comprising:
a base;
a plurality of solar cell units disposed at the base;
a light guide element having a plurality of integrally formed funnel-shaped light guide units, the light guide element being disposed at the base, each of the funnel-shaped light guide units guiding light to the respective solar cell unit; and
a plurality of lens units, each of the lens unit disposed at the respective funnel-shaped light guide unit.

2. The portable solar cell apparatus according to claim 1, wherein the funnel-shaped light guide units are disposed in an array.

3. The portable solar cell apparatus according to claim 1, wherein each of the funnel-shaped light guide units has at least one reflecting surface, and the reflecting surface reflects part of light passing through the corresponding lens unit to the corresponding solar cell unit.

4. The portable solar cell apparatus according to claim 3, wherein the reflecting surface is a flat surface.

5. The portable solar cell apparatus according to claim 3, wherein the reflecting surface is a curved surface.

6. The portable solar cell apparatus according to claim 1, wherein the solar cell units are disposed at the base in an array.

7. The portable solar cell apparatus according to claim 1, wherein each of the solar cell units is made of monocrystalline silicon, polycrystalline silicon, amorphous silicon, or a III-V material.

8. The portable solar cell apparatus according to claim 1, wherein each of the lens units cooperates with the respective funnel-shaped light guide unit to guide and concentrate light to the respective solar cell unit.

9. The portable solar cell apparatus according to claim 1, wherein the lens units are integrally formed.

10. The portable solar cell apparatus according to claim 1, wherein each of the lens units is a Fresnel lens and has a plurality of light concentrating structures.

11. The portable solar cell apparatus according to claim 10, wherein the Fresnel lens is a point concentrator, and the light concentrating structures are arranged in homocentric circles.

12. The portable solar cell apparatus according to claim 11, wherein the light concentrating structures and the corresponding solar cell unit are rectangles with the same length-width ratio.

13. The portable solar cell apparatus according to claim 10, wherein the Fresnel lens is a line concentrator, and the light concentrating structures are linear and are arranged in parallel.

14. The portable solar cell apparatus according to claim 13, wherein the solar cell units are strip-shaped.

15. The portable solar cell apparatus according to claim 1, wherein light spots generated by concentrating light by each of the lens units are stacked, respectively, and the shape of the light spots corresponds to that of the respective solar cell unit.

16. The portable solar cell apparatus according to claim 1, wherein each of the lens units is made of polymethyl methacrylate, polystyrene, or polycarbonate plastic.
